(19) United States
(12) Patent Application Publication
(10) Pub. No.: US 2026/0255977 A1
(43) Pub. Date: Aug. 27, 2026

(54) SYSTEM-IN-PACKAGE ASSEMBLY, AND PACKAGING METHOD AND MANUFACTURING METHOD THEREFOR

(71) Applicant: SPREADTRUM COMMUNICATIONS (SHANGHAI) CO., LTD., Shanghai (CN)

(72) Inventors: Li YAO, Shanghai (CN); Hongcheng YIN, Shanghai (CN)

(73) Assignee: SPREADTRUM COMMUNICATIONS (SHANGHAI) CO., LTD., Shanghai (CN)

(21) Appl. No.: 18/714,370

(22) PCT Filed: Nov. 22, 2022
(86) PCT No.: PCT/CN2022/133455

§ 371 Date: May 29, 2024

(30) Foreign Application Priority Data
Nov. 30, 2021 (CN) 202111444181.3

(51) Int. Cl. H10W 42/20; H10W 74/01

(52) U.S. Cl. CPC H10W 42/267; H10W 74/01

(57) ABSTRACT

Disclosed are a system-in-package (SIP) assembly, a packaging method and a manufacturing method thereof. An integrated outer surface of a plastic package of the SIP assembly includes at least two shielding layer regions, and a spacing region is provided between any two of the shielding layer regions. By providing the shielding layer on the integrated outer surface of the plastic package, the shield body can be prevented from becoming a medium for high-frequency and high-power noise to affect normal operation of surrounding devices. That is, the present disclosure prevents noise signals in shielded regions from interfering with each other, thus protecting a specific device and circuit.

### CROSS-REFERENCE TO RELATED APPLICATIONS

The present application is a National Phase of International Application No. PCT/CN2022/133455, filed on Nov. 22, 2022, which claims priority to Chinese Patent Application No. 202111444181.3, filed on Nov. 30, 2021, the contents of which are incorporated herein by reference in their entireties.

### TECHNICAL FIELD

Embodiments of the present disclosure relate to the field of system-in-package (SIP) technologies and, in particular, to an SIP assembly, and a packaging method and a manufacturing method thereof.

### BACKGROUND

In conventional package or module products, an electromagnetic interference (EMI) coating is used to shield EMI. The EMI coating is feasible at a low frequency and a low power. In case of a power amplifier (PA) in a package, due to surface continuity of the EMI coating, the shield body is not electrically independent, but instead becomes a medium for high-frequency and high-power noise, which may adversely affect normal operation of surrounding devices.

Alternatively, a metal can process is used to shield the EMI. However, due to entire coverage of the metal can, with the increasing of stacked structures, the whole package assembly becomes larger because of the shield cover. This scheme does not meet requirements of future package development, and the shield body also cannot be electrically independent.

Alternatively, a mounted circuit board is subjected to plastic packaging to form an entire plastic package. For mutually interfering electronic components on a circuit substrate, a scribe line is provided between the electronic components. The whole plastic package is cut off based on the scribe line to obtain two or more separated plastic packages. Then, a shielding layer is sprayed. The shield body is interrupted through spacing between the separated plastic packages. For a small chip, the scribe line formed at a corresponding position of the substrate will occupy corresponding space of the substrate, and thus the method is not applicable for miniaturization. On the other hand, for a large chip, in response to determination of interference between chips or regions, a spacing path may possibly be located on a certain component or a certain entire region, and it is thus impossible to cut the component or the entire region.

### SUMMARY

The technical problem to be solved by the present disclosure is to provide an SIP assembly, a packaging method and a manufacturing method thereof, to overcome the above defects in the prior art.

The present disclosure solves the technical problem with the following technical solutions:

The present disclosure provides an SIP assembly. An integrated outer surface of a plastic package of the SIP assembly includes at least two shielding layer regions. A spacing region is provided between any two of the shielding layer regions.

In an embodiment, the SIP assembly includes a substrate. At least two devices are provided on the substrate. A position of the spacing region corresponds to a first region on the substrate. The first region includes a region between mounting positions of any two of the devices on the substrate.

In an embodiment, the SIP assembly includes a substrate. At least one interfering source device and at least one interfered device corresponding to the interfering source device are provided on the substrate. A position of the spacing region corresponds to a second region on the substrate. The second region includes a region between a mounting position of the interfering source device and a mounting position of the corresponding interfered device on the substrate.

The present disclosure provides a method for packaging an SIP assembly. The method includes: forming at least two shielding layer regions on an integrated outer surface of a plastic package of the SIP assembly. A spacing region is provided between any two of the shielding layer regions.

In an embodiment, the SIP assembly includes a substrate. At least two devices are provided on the substrate. Prior to the forming the at least two shielding layer regions on the integrated outer surface of the plastic package of the SIP assembly, the method includes: determining a first region on the substrate, the first region including a region between mounting positions of any two of the devices on the substrate; and determining a position of the spacing region based on the first region.

In an embodiment, the SIP assembly includes a substrate. At least one interfering source device and at least one interfered device corresponding to the interfering source device are provided on the substrate. Prior to the forming the at least two shielding layer regions on the integrated outer surface of the plastic package of the SIP assembly, the method includes: determining a second region on the substrate, the second region including a region between a mounting position of the interfering source device and a mounting position of the corresponding interfered device on the substrate; and determining a position of the spacing region based on the second region.

The present disclosure provides a method for manufacturing an SIP assembly. The method includes: placing a die on an outer surface of the SIP assembly; forming, based on an EMI coating process, a shielding layer on an integrated outer surface of a plastic package of the SIP assembly including the die; and removing the die to obtain a spacing region and at least two shielding layer regions, a position where the die is placed is a position of the spacing region.

In an embodiment, the method further includes: providing a substrate; providing at least two devices on a surface of the substrate; performing plastic packaging on the substrate to obtain the SIP assembly; and manufacturing the die based on a position of a first region on the substrate, the first region includes a region between mounting positions of any two of the devices on the substrate, or manufacturing the die based on a position of a second region on the substrate, the second region includes a region between a mounting position of an interfering source device and a mounting position of a corresponding interfered device in the at least two devices on the substrate.

The present disclosure provides a method for manufacturing an SIP assembly. The manufacturing method includes: forming, based on an EMI coating process, a shielding layer on an integrated outer surface of a plastic package of the SIP assembly; and etching the shielding layer based on a laser etching process to obtain a spacing region and at least two shielding layer regions, the spacing region is provided between any two of the shielding layer regions.

In an embodiment, the manufacturing method further includes: providing a substrate; providing at least two devices on a surface of the substrate; and performing plastic packaging on the substrate to obtain the SIP assembly. A position of the spacing region is determined based on a position of a first region on the substrate. The first region includes a region between mounting positions of any two of the devices on the substrate. Or, the position of the spacing region is determined based on a position of a second region on the substrate. The second region includes a region between a mounting position of an interfering source device and a mounting position of a corresponding interfered device in the at least two devices on the substrate.

The present disclosure has the following beneficial effects: by providing the shielding layer on the integrated outer surface of the plastic package, the shield body can be prevented from becoming a medium for high-frequency and high-power noise to affect normal operation of surrounding devices. That is, the present disclosure prevents noise signals in shielded regions from interfering with each other, thus protecting the specific devices and circuits.

### BRIEF DESCRIPTION OF DRAWINGS

To describe the technical solutions in embodiments of the present disclosure more clearly, the following content briefly describes the accompanying drawings required in the embodiments. It is appreciated that, the accompanying drawings in the following description merely show some embodiments of the present disclosure, and person of ordinary skill in the art can still derive other drawings from these accompanying drawings without creative efforts.

FIG. 1 is a schematic view of a shielding layer region on an outer surface of an SIP assembly according to Embodiment 1 of the present disclosure;

FIG. 2 is a schematic sectional view of an SIP assembly according to Embodiment 2 of the present disclosure;

FIG. 3 is a schematic view of a shielding layer region on an outer surface of an SIP assembly according to Embodiment 2 of the present disclosure;

FIG. 4 is a schematic sectional view of an SIP assembly according to Embodiment 3 of the present disclosure;

FIG. 5 is a schematic view of a shielding layer region on an outer surface of an SIP assembly according to Embodiment 3 of the present disclosure;

FIG. 6 is a flowchart of a method for packaging an SIP assembly according to Embodiment 4 of the present disclosure;

FIG. 7 is a flowchart of a method for packaging an SIP assembly according to Embodiment 5 of the present disclosure;

FIG. 8 is a flowchart of a method for manufacturing an SIP assembly according to Embodiment 6 of the present disclosure; and

FIG. 9 is a flowchart of a method for manufacturing an SIP assembly according to Embodiment 7 of the present disclosure.

### DESCRIPTION OF EMBODIMENTS

The present disclosure is further described below through the following embodiments, but the present disclosure is not limited to the scope of the described embodiments.

### Embodiment 1

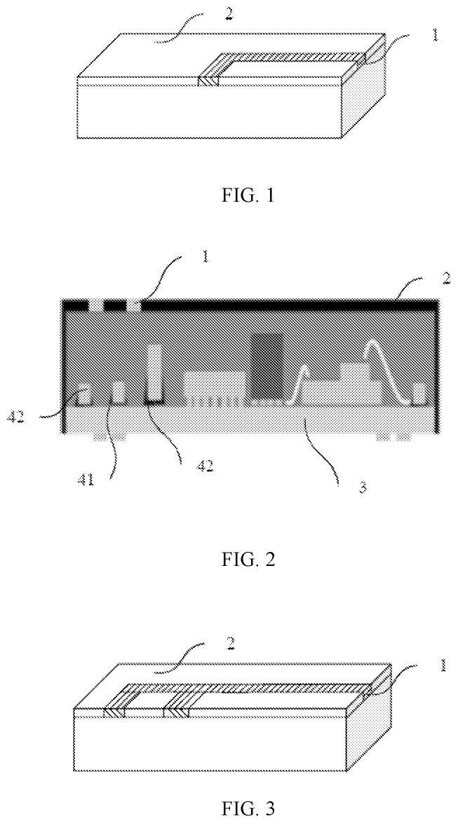

The present disclosure provides an SIP assembly. As shown in FIG. 1, an integrated outer surface of a plastic package of the SIP assembly includes at least two shielding layer regions 2. It is to be noted that the plastic package of the SIP assembly in this embodiment is formed as an entirety, the shielding layer regions are formed on the integrated outer surface of the plastic package, and it is understood that a spacing region is not obtained by slotting to the plastic package.

A spacing region 1 is provided between any two of the shielding layer regions 2.

It is to be noted that the whole outer surface of the SIP assembly is a shielding layer of the SIP assembly. In this embodiment, the shield body will not form a medium for high-frequency and high-power noise by providing a spacing of the shielding layer on the outer surface without additionally adding other hardware structures, thus preventing mutual interference between devices.

In this embodiment, by providing the shielding layer on the entire outer surface of the plastic package, the shield body can be prevented from becoming the medium for the high-frequency and high-power noise which may affect normal operation of surrounding devices on the SIP assembly. That is, the present disclosure prevents noise signals in shielded regions from interfering with each other, thus protecting the devices and the circuits.

### Embodiment 2

The SIP assembly in this embodiment is further improved on the basis of Embodiment 1. As shown in FIGS. 2-3, the SIP assembly includes a substrate 3. At least two devices are provided on the substrate 3.

A position of the spacing region 1 corresponds to a first region on the substrate 3.

The first region includes a region between mounting positions of any two of the devices on the substrate 3.

It is to be noted that the spacing region 1 can be provided corresponding to a region between each two of all devices or several particular devices as required. Alternatively, as shown in FIG. 2, in view of the possible influence of the high-frequency and high-power noise, the spacing region 1 is provided corresponding to a region between a device 41 (such as a PA) for generating the high-frequency and high-power noise and an adjacent device 42.

In this embodiment, in order to prevent the influence of the high-frequency and high-power noise of some devices on other devices, the position of the spacing region is further determined based on a mounting position of each device on the SIP assembly. By providing the shielding layer on the entire integrated outer surface of the plastic package, the shield body can be prevented from becoming the medium for the high-frequency and high-power noise to affect normal operation of surrounding devices on the SIP assembly. That is, the present disclosure prevents noise signals in shielded regions from interfering with each other, thus protecting the devices and the circuits.

### Embodiment 3

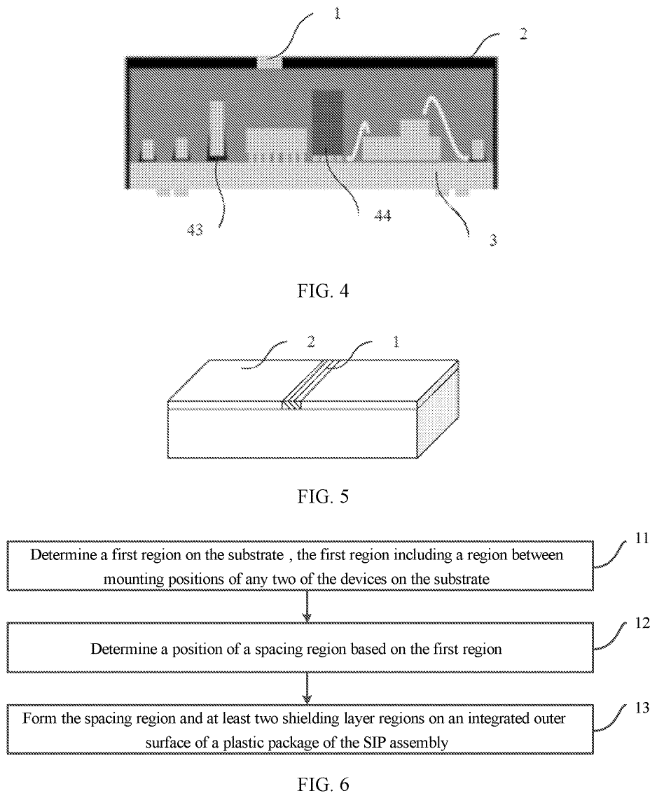

The SIP assembly in this embodiment is further improved on the basis of Embodiment 1. As shown in FIGS. 4-5, the SIP assembly includes a substrate 3. At least one interfering source device 43 and at least one interfered device 44 corresponding to the interfering source device 43 are provided on the substrate 3.

A position of the spacing region 1 corresponds to a second region on the substrate 3.

The second region includes a region between a mounting position of the interfering source device 43 and a mounting position of the corresponding interfered device 44 on the substrate 3.

It is to be noted that in actual applications, according to the interference between devices in the SIP assembly, interference suppression can be realized between mutually interfering devices. Hence, after knowing devices arranged in the SIP assembly, the interfering source device and the corresponding interfered device are determined, and the spacing region is further provided corresponding to the region between the interfering source device and the corresponding interfered device.

In addition, in view of EMI shielding of the shielding layer, after the spacing region is formed, effective EMI shielding can further be ensured. A width of the spacing region can further be determined in combination with experimental detection parameters, for example, based on a radiated interference range of the interfering source device.

It is to be noted that for a big integrated chip, interference may exist between multiple devices, or between multiple regions. When the spacing region is provided, an interfering region and an interfered region can be obtained with a region or a region coverage defined by the plurality of devices as the unit. Thereafter, the spacing region is provided at a corresponding region between the two regions.

In this embodiment, in order to prevent the influence of the interfering source device on the corresponding interfered device, the position of the spacing region is further determined based on a mounting position of the interfering source device against the corresponding interfered device. By providing the shielding layer on the entire integrated outer surface of the plastic package, the shield body can be prevented from becoming the medium for the high-frequency and high-power noise to affect normal operation of the interfered device on the SIP assembly. That is, the present disclosure prevents noise signals in shielded regions from interfering with each other, thus protecting the devices and the circuits.

### Embodiment 4

The present disclosure provides a method for packaging an SIP assembly. The SIP assembly includes a substrate. At least two devices are provided on the substrate. As shown in FIG. 6, the packaging method includes:

In step 11, a first region on the substrate is determined, the first region including a region between mounting positions of any two of the devices on the substrate.

It is to be noted that a spacing region can be provided corresponding to a region between each two of all devices or several particular devices as required. Alternatively, in view of the influence of the high-frequency and high-power noise, the spacing region is provided corresponding to a region between a device (such as a PA) for generating the high-frequency and high-power noise and an adjacent device.

In step 12, a position of a spacing region is determined based on the first region.

In step 13, the spacing region and at least two shielding layer regions are formed on an integrated outer surface of a plastic package of the SIP assembly.

The spacing region is provided between any two of the shielding layer regions. It is to be noted that the plastic package of the SIP assembly in the this embodiment is formed as an entirety, the shielding layer regions are formed on the integrated outer surface of the plastic package, and it is understood that the spacing region is not obtained by slotting to the plastic package.

It is to be noted that the whole outer surface of the SIP assembly is a shielding layer of the SIP assembly. In this embodiment, the shield body will not form a medium for high-frequency and high-power noise by providing a spacing of the shielding layer on the outer surface without additionally adding other hardware structures, thus preventing mutual interference between devices.

In this embodiment, in order to prevent the influence of the high-frequency and high-power noise of some device on other devices, the position of the spacing region is further determined based on a mounting position of each device on the SIP assembly. By providing the shielding layer on the entire integrated outer surface of the plastic package, the shield body can be prevented from becoming the medium for the high-frequency and high-power noise to affect normal operation of surrounding devices on the SIP assembly. That is, the present disclosure prevents noise signals in shielded regions from interfering with each other, thus protecting the devices and the circuits.

### Embodiment 5

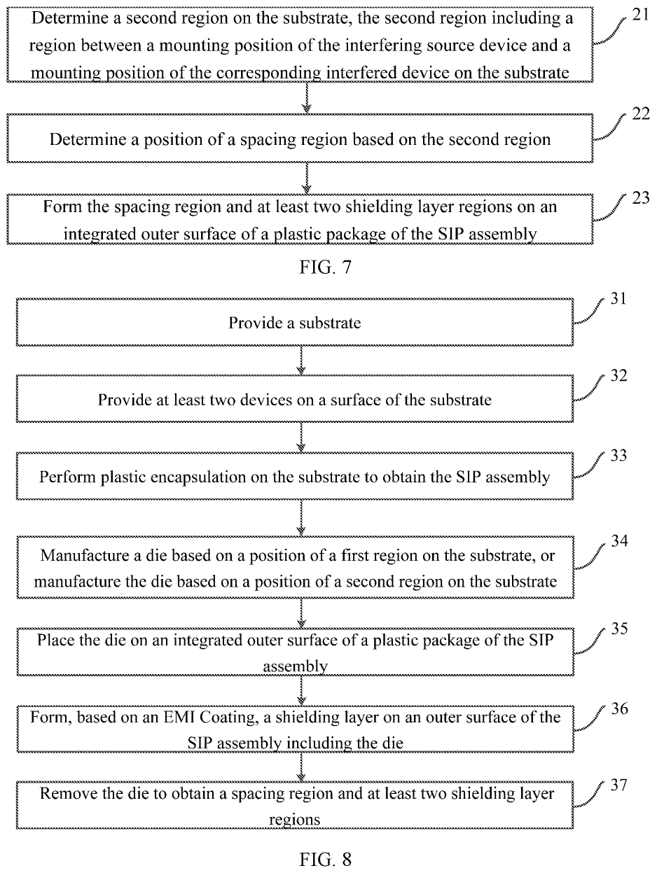

This embodiment further provides a method for packaging an SIP assembly. The SIP assembly includes a substrate. At least one interfering source device and at least one interfered device corresponding to the interfering source device are provided on the substrate. As shown in FIG. 7, the packaging method includes:

In step 21, a second region on the substrate is determined, the second region including a region between a mounting position of the interfering source device and a mounting position of the corresponding interfered device on the substrate.

It is to be noted that in actual applications, according to the interference between devices in the SIP assembly, interference suppression can be realized between mutually interfering devices. Hence, after knowing devices arranged in the SIP assembly, the interfering source device and the corresponding interfered device are determined, and the spacing region is further provided corresponding to the region between the interfering source device and the corresponding interfered device.

It is to be noted that for a big integrated chip, interference may exist between multiple devices, or between multiple regions. When the spacing region is provided, an interfering region and an interfered region can be obtained with a region or a region coverage defined by the plurality of devices as the unit. Thereafter, the second region is provided at a corresponding region between the two regions.

In step 22, a position of a spacing region is determined based on the second region.

In view of EMI shielding of the shielding layer, after the spacing region is formed, effective EMI shielding can further be ensured. A width of the spacing region can further be determined in combination with experimental detection parameters, for example, based on a radiated interference range of the interfering source device.

In step 23, the spacing region and at least two shielding layer regions are formed on an integrated outer surface of a plastic package of the SIP assembly.

The spacing region is provided between any two of the shielding layer regions. It is to be noted that the plastic package of the SIP assembly in the this embodiment is formed as an entirety, the shielding layer regions are formed on the integrated outer surface of the plastic package, and it is understood that the spacing region is not obtained by slotting to the plastic package.

In this embodiment, in order to prevent the influence of the interfering source device on the corresponding interfered device, the position of the spacing region is further determined based on a mounting position of the interfering source device against the corresponding interfered device. By providing the shielding layer on the entire integrated outer surface of the plastic package, the shield body can be prevented from becoming the medium for the high-frequency and high-power noise to affect normal operation of the interfered device on the SIP assembly. That is, the present disclosure prevents noise signals in shielded regions from interfering with each other, thus protecting the devices and the circuits.

### Embodiment 6

The present disclosure provides a method for manufacturing an SIP assembly. As shown in FIG. 8, the manufacturing method includes:

In step 31, a substrate is provided.

In step 32, at least two devices are provided on a surface of the substrate.

In step 33, plastic packaging is performed on the substrate to obtain the SIP assembly.

It is to be noted that the flowchart of the SIP assembly may further include, but is not limited to, substrate baking, solder paste printing, surface detection, surface mounting, optical detection, reflow soldering, flux removal, X-ray detection, mechanical slotting, plasma cleaning, wire bonding, etc. The flowchart is executed as required, and is not limited in the present disclosure.

In step 34, a die is manufactured based on a position of a first region on the substrate, or the die is manufactured based on a position of a second region on the substrate.

The first region includes a region between mounting positions of any two of the devices on the substrate. The second region includes a region between a mounting position of an interfering source device and a mounting position of a corresponding interfered device in the at least two devices on the substrate. In addition, a width of a spacing region can further be determined in combination with experimental detection parameters, for example, based on a radiated interference range of the interfering source device, thereby determining a width of the die. It is to be noted that the die may be manufactured before manufacture of the SIP assembly. For a big integrated chip, interference may exist between multiple devices, or between multiple regions. When the spacing region is provided, an interfering region and an interfered region can be obtained with a region or a region coverage defined by the plurality of devices as the unit. Thereafter, the second region is provided at a corresponding region between two regions.

In step 35, the die is placed on an integrated outer surface of a plastic package of the SIP assembly.

In step 36, based on an EMI coating process, a shielding layer is formed on an outer surface of the SIP assembly including the die. The EMI coating process mainly includes sputtering and spray coating. The coating material is manners. It is to be noted that the plastic package of the SIP assembly in the this embodiment is formed as an entirety, the shielding layer regions are formed on the integrated outer surface of the plastic package, and it is understood that the spacing region is not obtained by slotting to the plastic package.

In step 37, the die is removed to obtain a spacing region and at least two shielding layer regions, a position where the die is placed is the position of the spacing region.

In this embodiment, the shielding layer is formed under the assistance of the die, thereby automatically obtaining the region-divided shielding layer. By providing the shielding layer on the integrated outer surface of the plastic package, the shield body can be prevented from becoming the medium for the high-frequency and high-power noise to affect normal operation of the interfered device on the SIP assembly. That is, the present disclosure prevents noise signals in shielded regions from interfering with each other, thus protecting the devices and the circuits.

### Embodiment 7

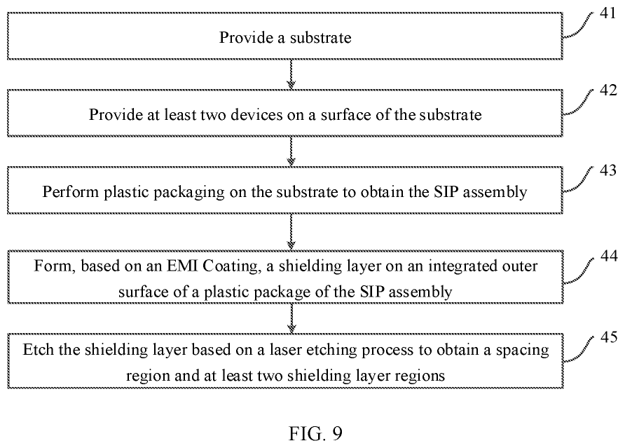

The present disclosure provides a method for manufacturing an SIP assembly. As shown in FIG. 9, the manufacturing method includes:

In step 41, a substrate is provided.

In step 42, at least two devices are provided on a surface of the substrate.

In step 43, plastic packaging is performed on the substrate to obtain the SIP assembly.

It is to be noted that the flowchart of the SIP assembly may further include, but is not limited to, substrate baking, solder paste printing, surface detection, surface mounting, optical detection, reflow soldering, flux removal, X-ray detection, mechanical slotting, plasma cleaning, wire bonding, etc. The flowchart is executed as required, and is not limited in the present disclosure.

In step 44, based on an EMI coating process, a shielding layer is formed on an integrated outer surface of a plastic package of the SIP assembly.

The EMI coating process mainly includes sputtering and spray coating. A coating material is entirely grounded to realize EMI shielding. The shielding layer may also be formed in other manners. It is to be noted that the plastic package of the SIP assembly in the this embodiment is formed as an entirety, the shielding layer regions are formed on the integrated outer surface of the plastic package, and it is understood that a spacing region is not obtained by slotting to the plastic package.

In step 45, the shielding layer is etched based on a laser etching process to obtain a spacing region and at least two shielding layer regions, the spacing region is provided between any two of the shielding layer regions.

The position of the spacing region is determined based on a position of a first region on the substrate. The first region includes a region between mounting positions of any two of the devices on the substrate. Alternatively, the position of the spacing region is determined based on a position of a second region on the substrate. The second region includes a region between a mounting position of an interfering source device and a mounting position of a corresponding interfered device in the at least two devices on the substrate. In addition, a width of the spacing region can further be determined in combination with experimental detection parameters, for example, based on a radiated interference range of an interfering source device. It is to be noted that for a big integrated chip, interference may exist between multiple devices, or between multiple regions. When the spacing region is provided, an interfering region and an interfered region can be obtained with a region or a region coverage defined by the plurality of devices as the unit. Thereafter, the second region is provided at a corresponding region between the two regions.

In this embodiment, the entire shielding layer is divided with the laser etching or other etching methods to obtain the spacing region. By providing the shielding layer on the integrated outer surface of the plastic package, the shield body can be prevented from becoming the medium for the high-frequency and high-power noise to affect normal operation of surrounding devices. That is, the present disclosure prevents noise signals in shielded regions from interfering with each other, thus protecting the devices and the circuits.

Although the embodiments of the present disclosure have been described above, those skilled in the art should understand that these are only examples, and the protection scope of the present disclosure is defined by the appended claims. Those skilled in the art can make various changes or modifications to these implementations without departing from the principle and essence of the present disclosure, but all these changes and modifications shall fall within the protection scope of the present disclosure.

1. A system-in-package (SIP) assembly, wherein an integrated outer surface of a plastic package of the SIP assembly comprises at least two shielding layer regions; and
a spacing region is provided between any two of the at least two shielding layer regions.

2. The SIP assembly according to claim 1, comprising a substrate with at least two devices provided on the substrate,
wherein a position of the spacing region corresponds to a first region on the substrate; and
the first region comprises a region between mounting positions of any two of the at least two devices on the substrate.

3. The SIP assembly according to claim 1, comprising a substrate with at least one interfering source device and at least one interfered device corresponding to the interfering source device provided on the substrate,
wherein a position of the spacing region corresponds to a second region on the substrate; and
the second region comprises a region between a mounting position of the interfering source device on the substrate and a mounting position of the corresponding interfered device on the substrate.

4. A method for packaging a system-in-package (SIP) assembly, comprising:
forming at least two shielding layer regions on an integrated outer surface of a plastic package of the SIP assembly,
wherein a spacing region is provided between any two of the at least two shielding layer regions.

5. The method for packaging an SIP assembly according to claim 4, wherein the SIP assembly comprises a substrate with at least two devices provided on the substrate; and prior to said forming the at least two shielding layer regions on the integrated outer surface of the plastic package of the SIP assembly, the method comprises:
determining a first region on the substrate, the first region comprising a region between mounting positions of any two of the at least two devices on the substrate; and
determining a position of the spacing region based on the first region.

6. The method for packaging an SIP assembly according to claim 4, wherein the SIP assembly comprises a substrate with at least one interfering source device and at least one interfered device corresponding to the interfering source device provided on the substrate; and prior to said forming the at least two shielding layer regions on the integrated outer surface of the plastic package of the SIP assembly, the method comprises:
determining a second region on the substrate, the second region comprising a region between a mounting position of the interfering source device on the substrate and a mounting position of the corresponding interfered device on the substrate; and
determining a position of the spacing region based on the second region.

7. A method for manufacturing a system-in-package (SIP) assembly, comprising:
placing a die on an outer surface of the SIP assembly;
forming, based on an electromagnetic interference (EMI) coating process, a shielding layer on an integrated outer surface of a plastic package of the SIP assembly including the die; and
removing the die to obtain a spacing region and at least two shielding layer regions, wherein a position where the die is placed is a position of the spacing region.

8. The method for manufacturing an SIP assembly according to claim 7, further comprising:
providing a substrate;
providing at least two devices on a surface of the substrate;
performing plastic packaging on the substrate to obtain the SIP assembly; and
manufacturing the die based on a position of a first region on the substrate, wherein the first region comprises a region between mounting positions of any two of the at least two devices on the substrate; or manufacturing the die based on a position of a second region on the substrate, wherein the second region comprises a region between a mounting position of an interfering source device in the at least two devices on the substrate and a mounting position of a corresponding interfered device in the at least two devices on the substrate.

9-10. (canceled)
